(19) United States
(12) Patent Application Publication
(10) Pub. No.: US 2024/0187593 A1
(43) Pub. Date: Jun. 6, 2024

(54) BITMASK COMPRESSION METHOD

(71) Applicant: KEYLABS AI LTD., Holon (IL)

(72) Inventors: Michael Seldin, Jerusalem (IL); George Maizel, Netanya (IL); Michael Abramov, Bat Yam (IL)

(73) Assignee: KEYLABS AI LTD., Holon (IL)

(21) Appl. No.: 18/279,486

(22) PCT Filed: Feb. 28, 2022
(86) PCT No.: PCT/IL2022/050221

§ 371 Date: Aug. 30, 2023

(30) Foreign Application Priority Data
Mar. 4, 2021 (IL) 281257

(51) Int. Cl. H04N 19/129; H04N 19/13; H04N 19/167; H04N 19/20

(52) U.S. Cl. CPC H04N 19/129; H04N 19/13; H04N 19/167; H04N 19/20; H04N 19/182

(57) ABSTRACT

The invention relates to a method for performing compression and decompression of bitmasks comprising the steps of: (a) Representing a bitmask as a 2D matrix where each cell contains a single Boolean value (bit), representing either a False value or a True value; (c) Packing the bitmask as an array of numbers, each number representing the length of a continuous run of False or True values obtained while scanning the mask matrix in row-major order; (d) Storing in computerized memory means only the values of the run lengths, but not the value related to each run (False or True); and (e) If the first scanned bit of the bitmask is True, then storing the first run of False values as having 0 instances.

### FIELD OF THE INVENTION

The present invention relates to a compression method. More particularly, given a digital image, the invention is concerned with a fast and efficient method whose purpose is to compress and store multiple Boolean masks that indicate which pixels of the image belong to different objects.

### BACKGROUND OF THE INVENTION

While annotating images and videos, one often needs to draw multiple Boolean masks over the image to indicate which pixels of the image belong to different objects.

While editing video annotation, multiple such masks may be loaded into client memory for different video frames, while only a fraction of these masks is used at a time.

It follows from the above that there is a need for a fast and efficient method for compressing currently unused masks in memory, and also for transferring these masks between client and server.

Using lossless data compression methods (deflate) such as Lempel-Ziv or Huffman coding is not an option, because there is no native deflate API (Application Programming Interface) in web browsers, and JS (JavaScript)-based implementations are too slow for many applications.

Moreover, the use of PNG (Portable Network Graphics) images is prohibitive because conversion from multiple PNG image BLOBs (Binary Large OBjects) to arrays of bits and back using native APIs is too complicated.

The invention is based on a novel compression/decompression method that is specially designed for compressing Boolean bit-masks in web applications.

The method is especially well-suited for simple-shaped masks (e.g. containing a single concave shape) under 1200×1200 pixels, and provides a balanced tradeoff between compression level and CPU demand.

### SUMMARY OF THE INVENTION

The invention relates to a method for performing compression and decompression of bitmasks comprising the steps of:
(I) Representing a bitmask as a 2D matrix where each cell contains a single Boolean value (bit), representing either a False value or a True value;
(II) Packing the bitmask as an array of numbers, each number representing the length of a continuous run of False or True values obtained while scanning the mask matrix in row-major order;
(III) Storing in computerized memory means only the values of the run lengths, but not the value related to each run (False or True); and
(IV) If the first scanned bit of the bitmask is True, then storing the first run of False values as having 0 instances.

According to one embodiment of the invention, a run lengths above 66810 items is encoded as several runs with 0-length runs of alternate value in between.

In another embodiment of the invention, the compression/decompression algorithm is applied in a web application. In a further embodiment of the invention, the compression/decompression algorithm is applied to digital images or videos.

In some embodiments, when packing the bitmask as detailed in (II) above, the mask is scanned in column-major order. In other embodiments of step (II) above, the run length values are then encoded as bytes using variable length encoding.

In some embodiments of step (IV) above in which the first scanned bit of the bitmask is True, the first scanned bit of the bitmask is the upper-left bit. In other embodiments of step (IV) above, if the first scanned bit of the bitmask is False, then the first run of True values is stored as having 0 instances.

The invention also encompasses apparatus for carrying out the method of the invention, comprising a CPU and memory means associated with said CPU, where said memory means dynamically store information provided by the CPU about run lengths, and where the CPU dynamically retrieves said information from said memory means whenever required.

According to an embodiment of the invention, the CPU is adapted to perform the following steps:
(I) Representing a bitmask as a 2D matrix where each cell contains a single Boolean value (bit), representing either a False value or a True value;
(II) Packing the bitmask as an array of numbers, each number representing the length of a continuous run of False or True values obtained while scanning the mask matrix in row-major order;
(III) Storing in memory means only the values of the run lengths, but not the value related to each run (False or True); and
(IV) If the first scanned bit of the bitmask is True, then storing the first run of False values as having 0 instances.

### BRIEF DESCRIPTION OF THE DRAWINGS

In the drawings:

FIG. 1 is a sample image where black pixels are encoded as True and gray pixels are encoded as False;

FIG. 2 is a sample image showing the run-length numbers that are saved for the image (a run-length is the length of a continuous run of identical values). Black pixels from the right border are concatenated with black pixels on the left border in the next row;

FIG. 3 is a table showing how the run length values are encoded in bytes;

FIG. 4 shows how run length above 66810 items may be encoded as several runs with 0-length runs of alternate value in between; and

FIG. 5 shows the row-major order scanning of a mask matrix.

### DETAILED DESCRIPTION OF THE INVENTION

A bitmask is represented as a 2D (two-dimensional) matrix where each cell contains a single Boolean value (bit) indicating whether a specific pixel is included in the mask or not.

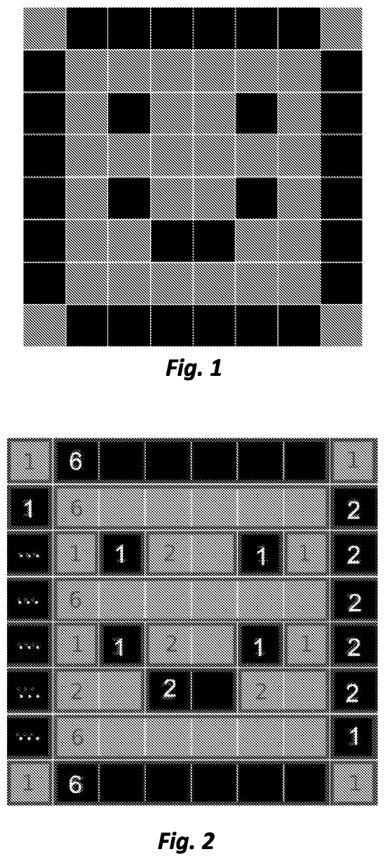

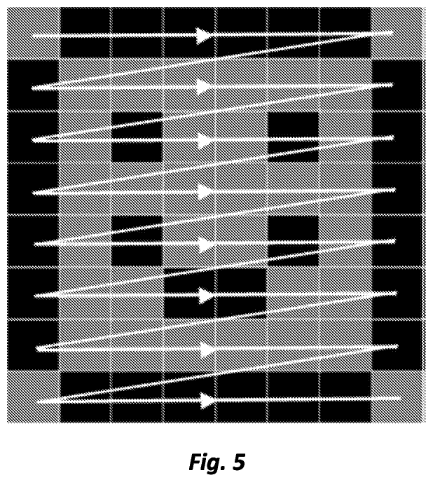

The mask is packed as an array of numbers, each number representing the length of a continuous run of False or True values, as shown in FIG. 1, while the mask matrix is scanned in row-major order as shown in FIG. 5.

Only run lengths, as shown in FIG. 2, are stored in the output, but not the run values (False or True). It is assumed that the first run will be of False values, and then True/False runs will alternate. If the upper-left bit of the mask is True, then the first run of False values will be stored as having 0 instances.

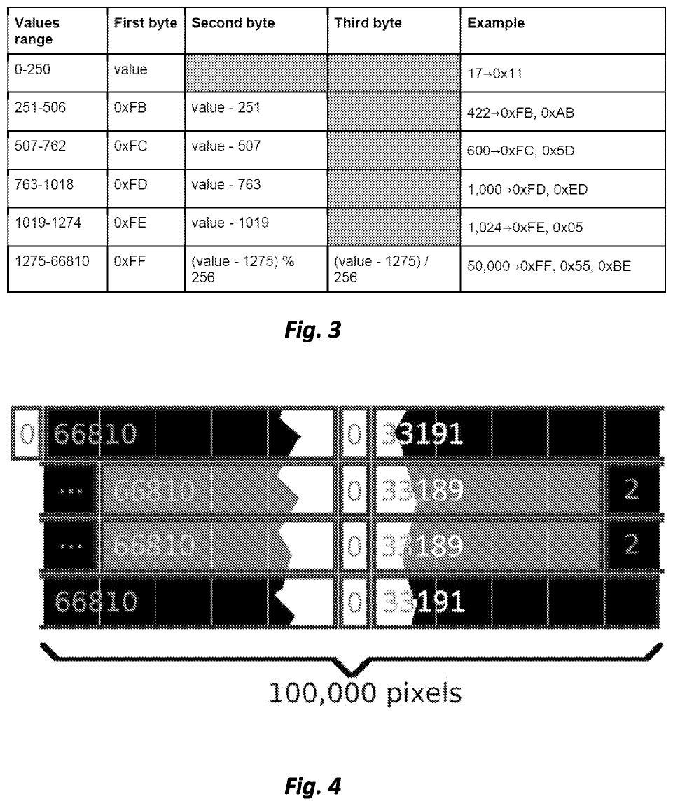

Run length values are then encoded as bytes using variable length encoding (1-3 bytes per value), as shown in FIG. 3. Compared to other variable-length encodings (like UTF-8), this encoding is optimized for packing relatively small numbers (<=1274) into fewer bytes on average at the cost of packing larger values into more bytes. In typical cases, there will be more occurrences of identical run length values under 1200 than longer runs.

Run lengths above 66810 items will not be represented directly, but will be encoded as several runs with 0-length runs of alternate value in between, as shown in FIG. 4 (e.g. run length 100,000 will be encoded as 66810, 0, 33190).

Decompression is done by performing in reverse order the actions described for the compression stage.

### DETAILED DESCRIPTION OF THE ILLUSTRATIVE EMBODIMENT

The code included in the illustrative embodiment that implements the operations discussed in the detailed description of the invention for both of the compression process and of the decompression process, is shown in the following, it being understood that the illustrative example shows a simplified process, provided for the purpose of illustration only, and is not meant to limit the invention in any way.

### Example 1

Compression process

```
function compress_mask (
  width: integer,
  height: integer,
  pixels: Array<boolean>
) begin
  result: Array<byte> = [ ];
  # encode image dimensions
  result = result + [byte(width), byte(width >> 8)];
  result = result + [byte(height), byte(height >> 8)];
  # The first encoded run-length value is expected to be a run
  # of False pixels. IF the first pixel is True, add 0-length run
  # of False pixels to the result.
  if pixels[0] == True then
    result = result + [0];
  end if
  count: integer = 1;
  i: integer = 0;
  while i < pixels.length do
    # if reached the end of identical pixels serie (at the end
    # of input or if the next pixel has a different value)...
    if i+1 == pixels.length or pixels[i+1] != pixels[i] then
      # ...write down the length of the current run...
    if count <= 250 then
    result = result + [byte(count)];
    elif count <= 506 then
    result = result + [0xFB, byte(count − 251)];
    elif count <= 762 then
    result = result + [0xFC, byte(count − 507)];
    elif count <= 1018 then
    result = result + [0xFD, byte(count − 763)];
    elif count <= 1274 then
    result = result + [0xFE, byte(count − 1019)];
    else
    result = result + [
          0xFF,
          byte((count − 1275) % 256),
          byte((count − 1275) / 256)
          ];
    end if
      # ... and reset the counter for the next run.
      count = 0;
    end if
    # if reached the maximum supported run-length...
    if count == 66810 then
      # ...write it down...
      result = result + [
        0xFF,
        byte((count − 1275) % 256),
        byte((count − 1275) / 256)
        ];
      # ...then insert intermediate 0-length run of
      # the opposite pixel value...
      result = result + [byte(0)];
      # ... and restart the counter.
    count = 0;
    end if
    count++;
    i++;
  done
  return result;
end
```

### Example 2

Decompression process

```
function decompress_mask (
  bytes: Array<byte>
) begin
  # decode image dimensions
  width: integer = bytes[0] | (bytes[1] << 8);
  height: integer = bytes[2] | (bytes[3] << 8);
  pixels: Array<boolean> = [ ];
  offset: integer = 4;
  # we start in a state where we are decoding a run of True pixels
  # with 0 pixels left, so that the code below will immediately
  # decode the first run-length from the actual data and interpret
  # it as a run-length of False pixels.
  current_value: boolean = True;
  count: integer = 0;
  while pixels.length < width * height do
    # if no pixels left in current run, decode the next
    # run length and flip pixel value to the opposite.
    # this check happens in a loop until non-empty run is found
    # because there may be 0-length runs that should not yield
    # any pixels.
    while count == 0 do
      # decode run length
    b1: byte = bytes[offset];
    offset = offset + 1;
    if b1 <= 250 then
    count = b1
    else
    b2: byte = bytes[offset];
    offset = offset + 1;
    if b1 == 251 then
      count = b2 + 251;
    elif b1 == 252 then
      count = b2 + 507;
    elif b1 == 253 then
      count = b2 + 763;
    elif b1 == 254 then
      count = b2 + 1019;
    else
      b3: byte = bytes[offset];
      offset = offset + 1;
      count = ((b3 << 8) | b2) + 1275;
    endif
    endif
      # flip pixel value
    current_value = not current_value;
    done
    pixels = pixels + [current_value];
    count = count − 1;
  done
  return {width, height, pixels};
end
```

All the above description and examples have been provided for the purpose of illustration and are not intended to limit the invention in any way. As will be apparent to the skilled person, the invention can be performed with many variations and with a variety of objects to be compressed and decompressed, all as defined in the appended claims.

1. A method for performing compression and decompression of bitmasks comprising the steps of:
(I) Representing a bitmask as a 2D matrix where each cell contains a single Boolean value (bit), representing either a False value or a True value;
(II) Packing the bitmask as an array of numbers, each number representing the length of a continuous run of False or True values obtained while scanning the mask matrix in row-major order;
(III) Storing in computerized memory means only the values of the run lengths, but not the value related to each run (False or True); and
(IV) If the first scanned bit of the bitmask is True, then storing the first run of False values as having 0 instances.

2. A method according to claim 1, where run lengths above 66810 items is encoded as several runs with 0-length runs of alternate value in between.

3. A method according to claim 1, where the compression/decompression algorithm is applied in a web application.

4. A method according to claim 1, where the compression/decompression algorithm is applied to digital images or videos.

5. A method according to claim 1(II), where the mask is scanned in column-major order.

6. A method according to claim 1(II) where the run length values are then encoded as bytes using variable length encoding.

7. A method according to claim 1(IV), where the first scanned bit of the bitmask is the upper-left bit.

8. A method according to claim 1(IV), where if the first scanned bit of the bitmask is False, then the first run of True values is stored as having 0 instances.

9. Apparatus for carrying out the method of claim 1, comprising a CPU and memory means associated with said CPU, where said memory means dynamically store information provided by the CPU about run lengths, and where the CPU dynamically retrieves said information from said memory means whenever required.

10. Apparatus as claimed in claim 9, wherein the CPU is adapted to perform the following steps:
(I) Representing a bitmask as a 2D matrix where each cell contains a single Boolean value (bit), representing either a False value or a True value;
(II) Packing the bitmask as an array of numbers, each number representing the length of a continuous run of False or True values obtained while scanning the mask matrix in row-major order;
(III) Storing in memory means only the values of the run lengths, but not the value related to each run (False or True); and
(IV) If the first scanned bit of the bitmask is True, then storing the first run of False values as having 0 instances.
